(19) United States
(12) Patent Application Publication
(10) Pub. No.: US 2019/0097302 A1
(43) Pub. Date: Mar. 28, 2019

(54) PATCH ANTENNA LAYER FOR TAMPER EVENT DETECTION

(71) Applicant: International Business Machines Corporation, Armonk, NY (US)

(72) Inventors: LAYNE A. BERGE, ROCHESTER, MN (US); JOHN R. DANGLER, ROCHESTER, MN (US); MATTHEW S. DOYLE, CHATFIELD, MN (US); THOMAS W. LIANG, ROCHESTER, MN (US); MANUEL OROZCO, ROCHESTER, MN (US)

(21) Appl. No.: 15/712,342

(22) Filed: Sep. 22, 2017

(51) Int. Cl. H01Q 1/22; H01Q 1/42; H01Q 21/30; H05K 1/18

(52) U.S. Cl. CPC H01Q 1/22; H05K 1/185; H01Q 21/30; H01Q 1/42

(57) ABSTRACT

A cryptographic printed circuit board (PCB) includes a patch antenna threat event detection layer and a resonant frequency monitoring component. The patch antenna threat event detection layer is embedded within a PCB layer stack of the cryptographic PCB and includes at least one antenna. The resonant frequency monitoring component is configured to monitor a resonant frequency associated with the at least one antenna and to trigger one or more tamper response operations responsive to detecting a resonant frequency shift.

### BACKGROUND

In some electronic devices, physical security mechanisms may be used to protect sensitive hardware and/or software (e.g., cryptographic modules). An example of a physical security standard is the United States Government Federal Information Processing Standards (FIPS) 140-2 Security Requirements for Cryptographic Modules—Level 4. The standard states that “[a]t this security level, the physical security mechanisms provide a complete envelope of protection around the cryptographic module with the intent of detecting and responding to all unauthorized attempts at physical access” (FIPS 140-42).

### SUMMARY

According to an embodiment, a cryptographic printed circuit board (PCB) is disclosed. The cryptographic PCB includes a patch antenna threat event detection layer and a resonant frequency monitoring component. The patch antenna threat event detection layer is embedded within a PCB layer stack of the cryptographic PCB and includes at least one antenna. The resonant frequency monitoring component is configured to monitor a resonant frequency associated with the at least one antenna and to trigger one or more tamper response operations responsive to detecting a resonant frequency shift.

According to another embodiment, a method of utilizing a patch antenna layer for tamper event detection is disclosed. The method includes monitoring a resonant frequency of at least one antenna of a patch antenna layer embedded within a PCB layer stack of a cryptographic PCB. The method includes triggering one or more tamper response operations responsive to detecting a resonant frequency shift of the at least one antenna.

According to yet another embodiment, an electronic device includes an electronic component, a cryptographic PCB, and a resonant frequency monitoring component. The cryptographic PCB is communicatively coupled to the electronic component. A patch antenna threat event detection layer is embedded within a PCB layer stack of the cryptographic PCB. The patch antenna threat event detection layer includes at least one antenna. The resonant frequency monitoring component is configured to monitor a resonant frequency associated with the at least one antenna and to trigger a tamper response operation responsive to detecting a resonant frequency shift.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 is a cross-sectional view of selected portions of a secured device that includes patch antenna threat event detection layer(s) embedded in a cryptographic printed circuit board (PCB) for tamper event detection, according to one embodiment.

FIG. 2 is a diagram illustrating multiple views of selected portions of a first patch antenna threat event detection layer embedded in the cryptographic PCB of FIG. 1, according to one embodiment.

FIG. 3A illustrates a cross-sectional view of a tamper event associated with the first patch antenna threat event detection layer depicted in FIG. 2, according to one embodiment.

FIG. 3B illustrates multiple views of the first patch antenna layer depicted in FIG. 2 after the tamper event of FIG. 3A that results in a resonant frequency shift, according to one embodiment.

FIG. 4 is a diagram illustrating multiple views of selected portions of a second patch antenna threat event detection layer embedded in the cryptographic PCB of FIG. 1, according to one embodiment.

FIG. 5A illustrates a cross-sectional view of a tamper event associated with the second patch antenna threat event detection layer depicted in FIG. 4, according to one embodiment.

FIG. 5B illustrates multiple views of the second patch antenna layer depicted in FIG. 4 after the tamper event of FIG. 5A that results in a resonant frequency shift, according to one embodiment.

FIG. 6 is a flow diagram illustrating a method of utilizing patch antenna threat event detection layer(s) embedded in a cryptographic PCB for tamper event detection, according to one embodiment.

### DETAILED DESCRIPTION

Secured devices, such as encryption modules, that are resistant to physical tampering are used in various computing systems to protect sensitive data and components. For example, stored data that might be effectively invulnerable to unauthorized access via software protocols might be relatively easily accessed by direct, physical means, even if the stored data is notionally protected by encryption. Such physical access might entail drilling through, or physical removal of, portions of an outer casing or packaging of an electronic component. Physical access to internal device components might allow various data protective features of the device to be overridden or avoided such that otherwise protected data could be accessed. For example, by making direct electrical connections to various internal components, an encryption module might be effectively disabled or overridden. Alternatively, physical access to internal device components might allow incoming and outgoing data to be monitored or redirected in an unauthorized manner. Furthermore, in some instances, even physical access to internal components merely for purposes of studying a device might be harmful from the standpoint of security in similar installed devices.

The present disclosure describes utilizing a path antenna layer (or multiple patch antenna layers) embedded in a printed circuit board (PCB) for tamper event detection in a secured device that is designed to be resistant to physical tampering in order to protect sensitive data and/or components of the secured device. The security threat detection scheme of the present disclosure includes monitoring a resonant frequency of the patch antenna layer(s) for resonant frequency changes. A resonant frequency (f_{c}) shift may be associated with a security threat, such as a hole drilled into the electronic device package (PCB cross-section). The electronic device may perform one or more tamper response operations, such as erasing sensitive data, self-destructing, etc. In some embodiments, the present disclosure utilizes one plane-pair PCB laminate construct, where the lower plane (Z-axis when viewed in cross-section) becomes a finely tuned patch antenna which resonates as the outer plane is drilled, creating a hole. The cryptographic security solution of the present disclosure reduces impact to the PCB cross-section and/or electronic enclosure. Enabling cryptographic card threat detection while reducing the number of additional physical layers and cost to the PCB may provide advantages compared to other threat detection security schemes that may consume physical copper layers (more than one, often 4 or more layers) which otherwise could be used for wiring layers.

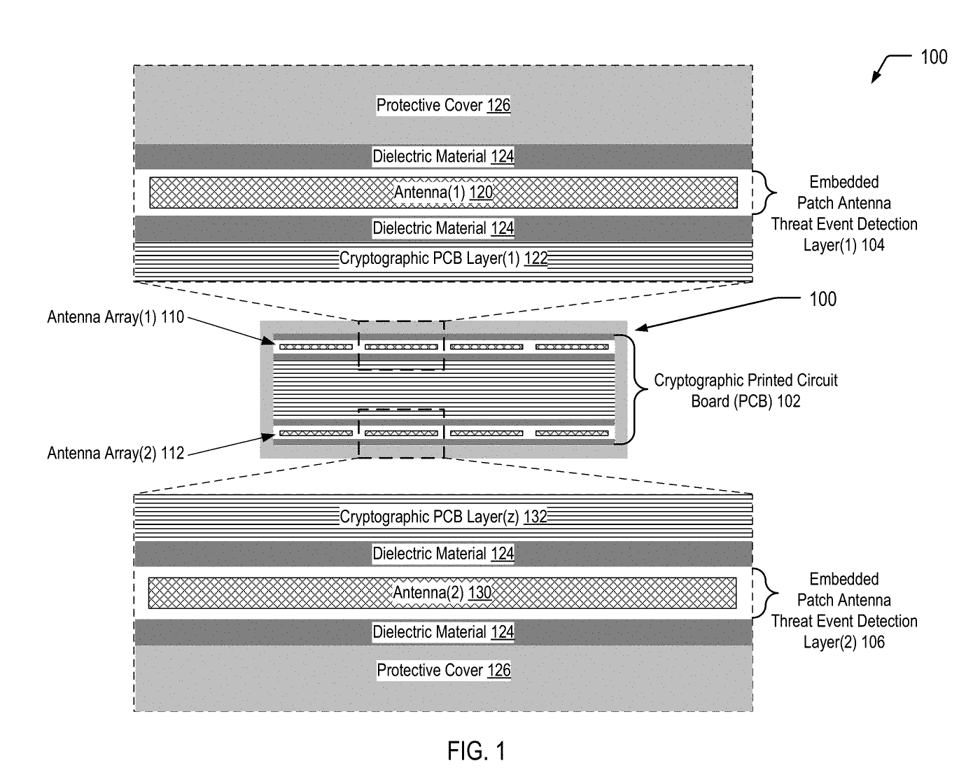

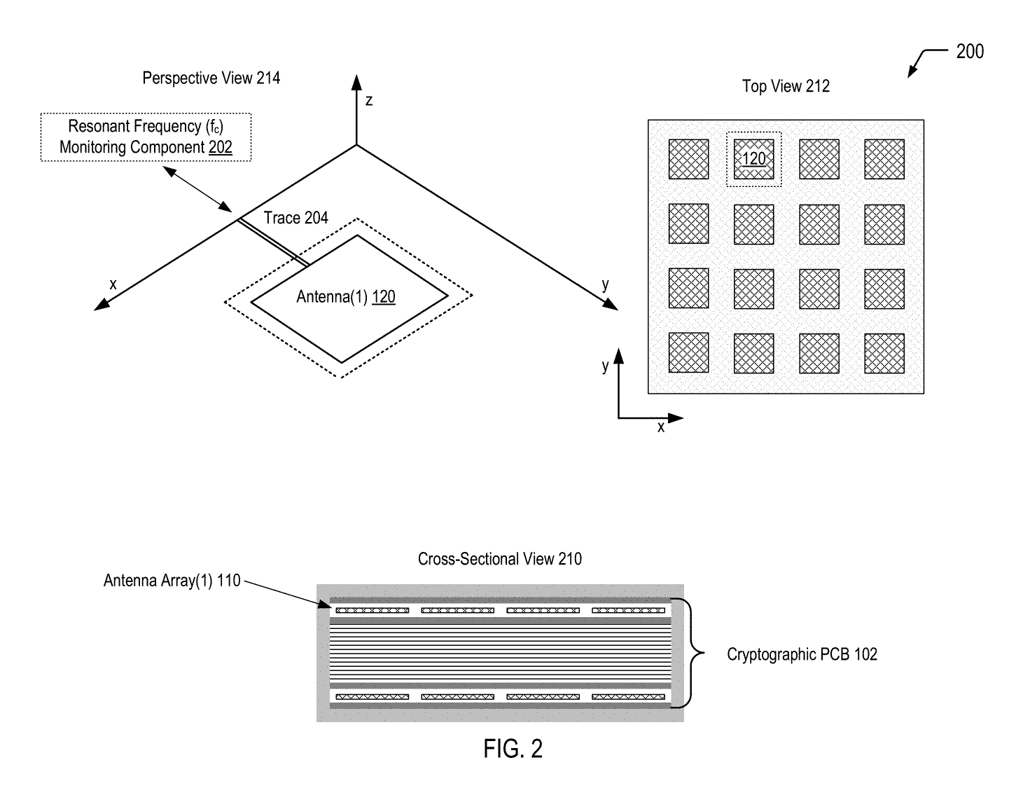

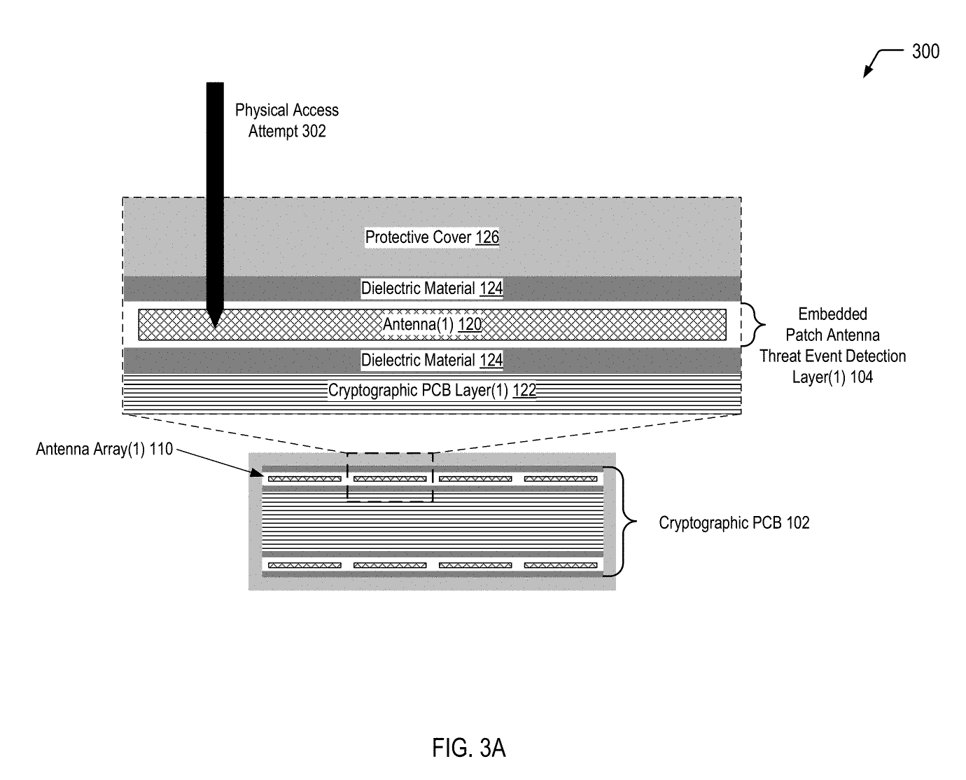

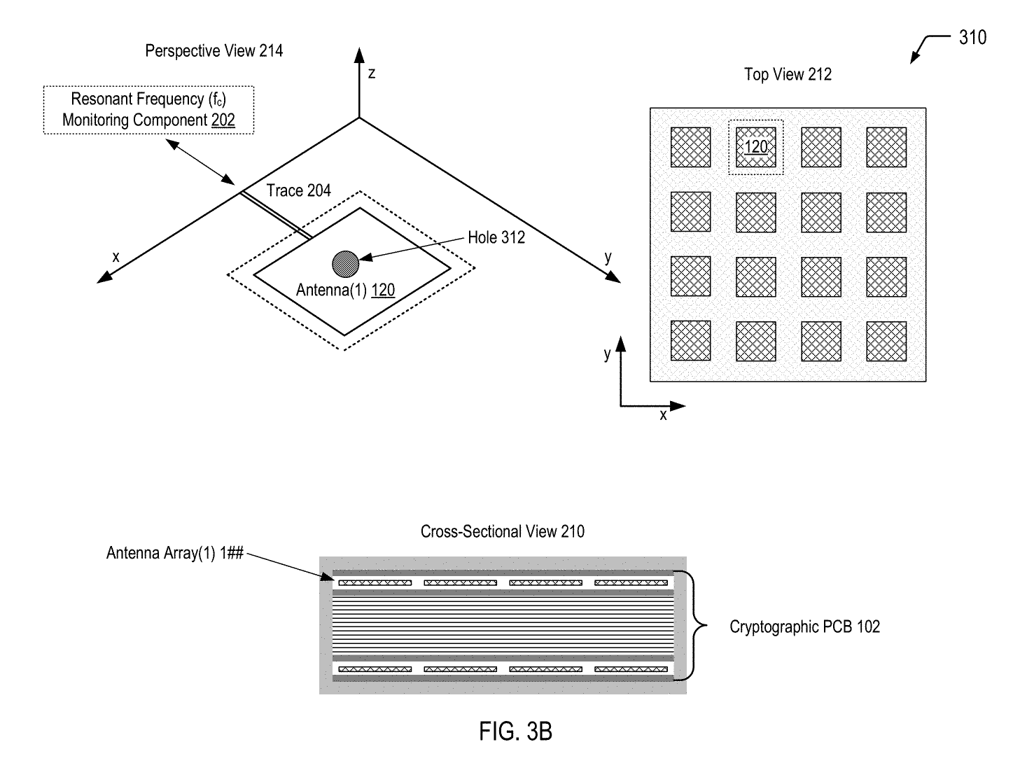

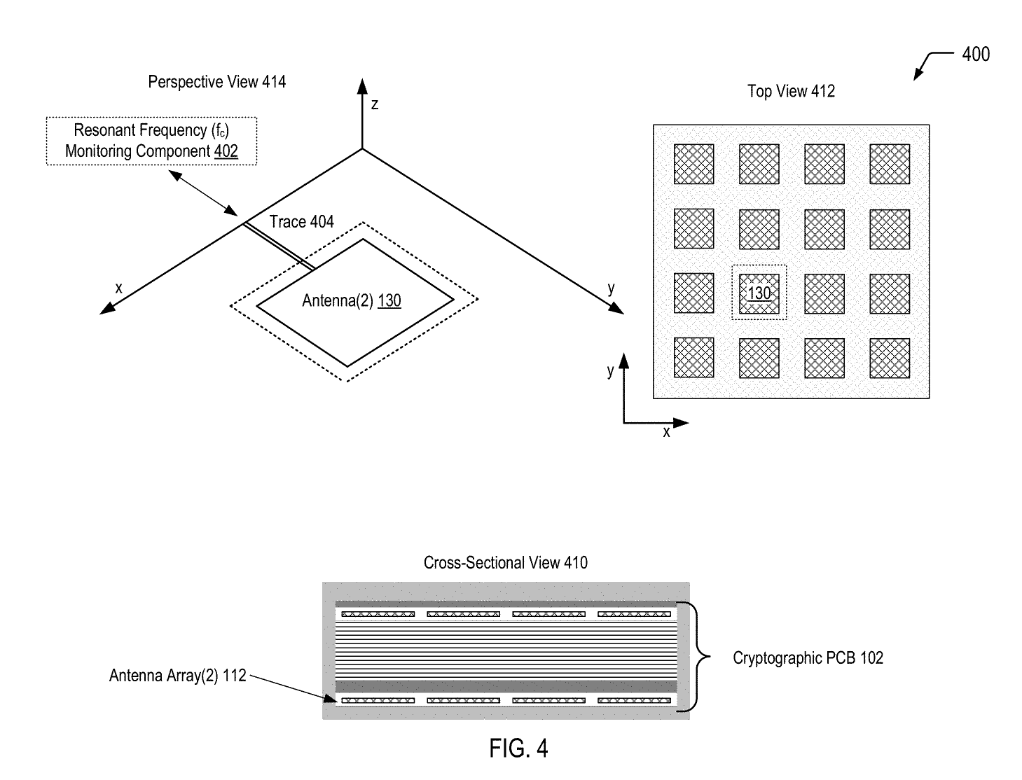

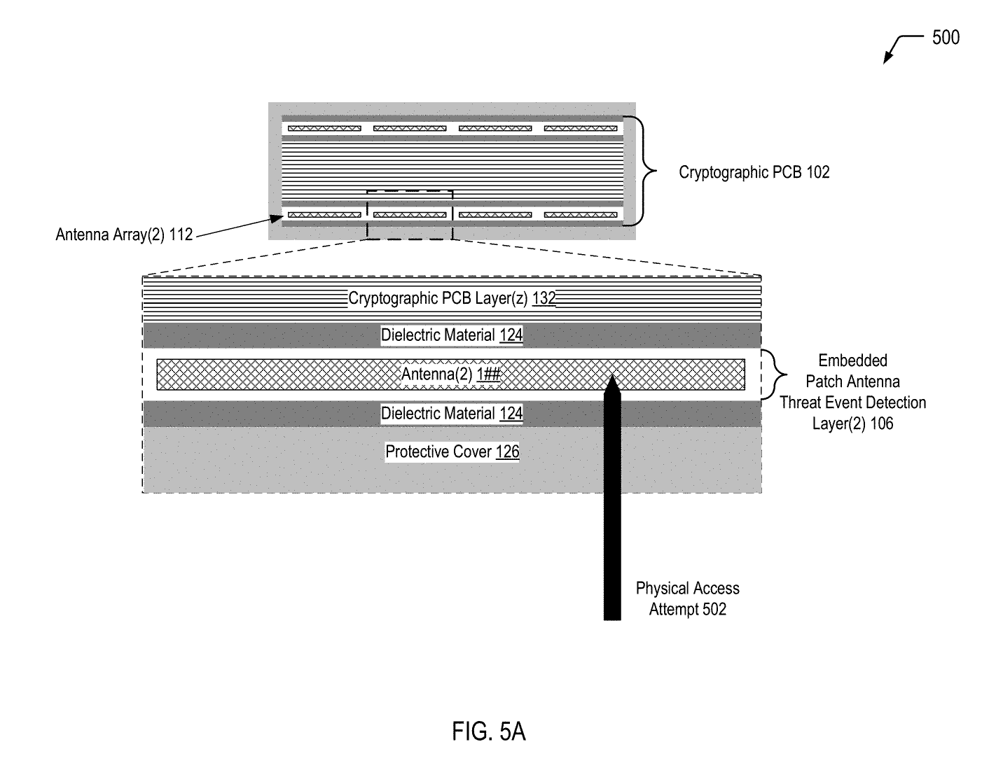

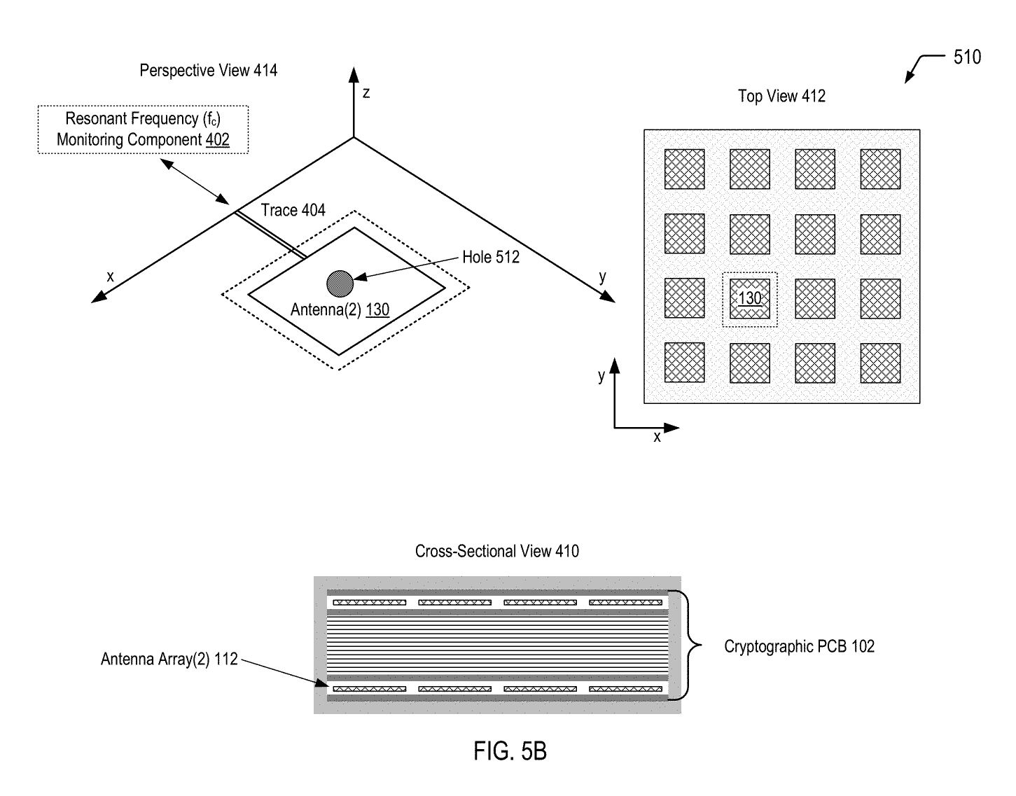

FIG. 1 is a diagram 100 that illustrates a cross-sectional view of a portion of a secured device 100 that includes patch antenna threat event detection layer(s) embedded in a cryptographic PCB 102 for tamper event detection, according to one embodiment. In the particular embodiment depicted in FIG. 1, the cryptographic PCB 102 includes a first patch antenna threat detection layer 104 embedded within a PCB layer stack and a second patch antenna threat detection layer 106 embedded within the PCB layer stack. As illustrated and further described herein with respect to FIGS. 2 and 3A-3B, the first patch antenna threat detection layer 104 may enable detection of an attempt to physically access the cryptographic PCB 102 via a “top” surface (when viewed in cross-section). As illustrated and further described herein with respect to FIGS. 4 and 5A-5B, the second patch antenna threat detection layer 106 may enable detection of an attempt to physically access the cryptographic PCB 102 via a “bottom” surface (when viewed in cross-section). In other embodiments, an alternative number and/or arrangement of patch antenna layers may be utilized for threat event detection.

FIG. 1 illustrates an embodiment in which the first embedded patch antenna threat event detection layer 104 includes a first antenna array 110, and the second embedded patch antenna threat event detection layer 106 includes a second antenna array 112. FIG. 2 further illustrates multiple views of selected portions of the first antenna array 110, and FIG. 4 further illustrates multiple views of selected portions of the second antenna array 112. In alternative embodiments, the first antenna array 110 and/or second antenna array 112 may include an alternative number and/or arrangement of antenna(s). As described further herein, utilizing an array of antennas may enable detection of a location of a physical access attempt (e.g., for selective tamper response operations).

Referring to the top of FIG. 1, an exploded view illustrates a selected portion of the cryptographic PCB 102 that includes the first patch antenna threat detection layer 104. The selected portion illustrates a first antenna 120 of the first antenna array 110 disposed within the first patch antenna threat detection layer 104. The exploded view illustrates that the first antenna 120 may overly a first cryptographic PCB layer 122. A first layer of dielectric material 124 may separate the first patch antenna threat detection layer 104 from the first cryptographic PCB layer 122, and a second layer of dielectric material 124 may be utilized to electrically isolate the first patch antenna threat detection layer 104 from a protective cover 126.

Referring to the bottom of FIG. 1, an exploded view illustrates a selected portion of the cryptographic PCB 102 that includes the second patch antenna threat detection layer 106. The selected portion illustrates a second antenna 130 of the second antenna array 112 disposed within the second patch antenna threat detection layer 104. The exploded view illustrates that the second antenna 130 may be disposed adjacent to another cryptographic PCB layer 132 (identified as “Cryptographic PCB Layer(z)” in FIG. 1). A first layer of dielectric material 124 may separate the second patch antenna threat detection layer 106 from the z^{th} cryptographic PCB layer 132, and a second layer of dielectric material 124 may be utilized to electrically isolate the second patch antenna threat detection layer 106 from a protective cover 126.

While not shown in FIG. 1, FIG. 2 illustrates that the first antenna 120 of the first antenna array 110 may be communicatively coupled to a resonant frequency monitoring component 202 for threat event detection. The resonant frequency monitoring component 202 may be configured to monitor a resonant frequency of the individual antennas (including the first antenna 120) of the first antenna array 110. As illustrated and further described herein with respect to FIGS. 3A and 3B, when the first patch antenna layer 104 is drilled, a hole 312 is formed that results in a shift of the resonant frequency. The resonant frequency monitoring component 202 may detect the shift in resonant frequency and may trigger one or more tamper response operations.

While not shown in FIG. 1, FIG. 4 illustrates that the second antenna 130 of the second embedded patch antenna threat detection layer 106 may be communicatively coupled to a resonant frequency monitoring component 402 for threat event detection. The resonant frequency monitoring component 402 may be configured to monitor a resonant frequency of the individual antennas (including the second antenna 130) of the second antenna array 112. As illustrated and further described herein with respect to FIGS. 5A and 5B, when the second patch antenna layer 106 is drilled, a hole 512 is formed that results in a shift of the resonant frequency. The resonant frequency monitoring component 402 may detect the shift in resonant frequency and may trigger one or more tamper response operations.

In a particular embodiment, the tamper response operation(s) may correspond to one or more actions to prevent or limit access to a component of the secured device 100. To illustrate, the action(s) may include shutting down the component or a portion thereof, transmitting an alarm signal to the internal component, transmitting an alarm signal to an external component, sounding an audible alarm, triggering a visual alarm, rendering the internal component inoperable, physically destroying the internal component or a portion thereof, erasing electronically stored data, encrypting internal data, overwriting stored data with dummy data, or any combination thereof (among other alternatives).

Thus, FIG. 1 illustrates an example of a secured device that utilizes patch antenna threat event detection layer(s) embedded in a cryptographic PCB for tamper event detection. As illustrated and further described herein, a physical access attempt may result in a shift of a resonant frequency. Detection of such a resonant frequency shift may trigger one or more tamper response operations. In some cases, the tamper detection capability of the secured device of FIG. 1 may be sufficient to satisfy FIPS 140-2 Security Requirements for Cryptographic Modules—Level 4 (among other possible security standards).

Referring to FIG. 2, a diagram 200 illustrates multiple views of selected portions of the first patch antenna threat event detection layer 104 embedded in the cryptographic PCB 102 depicted in FIG. 1, according to one embodiment. The multiple views include a cross-sectional view 210 that corresponds to the cross-sectional view depicted in FIG. 1, a top view 212 of the first antenna array 110, and a perspective view 214 that illustrates a portion of the first antenna array 110 that includes the first antenna 120.

In the particular embodiment depicted in FIG. 2, the top view 212 illustrates an example in which the first antenna array 110 includes a 4×4 array of antennas. It will be appreciated that alternative number and/or arrangement of antenna elements (including a single patch antenna) may be utilized. The perspective view 214 illustrates that the first antenna 120 of the first antenna array 110 may be communicatively coupled to a resonant frequency (f_{c}) monitoring component 202 by a trace 204. Illustrative, non-limiting examples of methods of detecting a shift in resonant frequency of the first antenna 120 include a phase-locked loop (PLL) circuit, frequency counter(s), or a frequency modulation (FM) carrier detection circuit such as a radio tuning circuit.

FIG. 3A illustrates a cross-sectional view 300 of a tamper event associated with the first patch antenna threat event detection layer 104, according to one embodiment. For illustrative purposes only, FIG. 3A depicts a physical access attempt 302 that penetrates through the protective cover 126 and the dielectric material 124 into the first embedded patch antenna threat event detection layer 104. It will be appreciated that the physical access attempt 302 may penetrate further into the cryptographic PCB 102.

Referring to FIG. 3B, a diagram 310 illustrates multiple views of the first patch antenna layer after the tamper event of FIG. 3A that results in a resonant frequency shift, according to one embodiment. The physical access attempt 302 of FIG. 3A results in a hole 312 in the first antenna 120. The hole 312 results in a resonant frequency shift that may be detected by the resonant frequency monitoring component 202 that is communicatively coupled to the first antenna 120 by the trace 204.

A three-dimensional (3D) simulation was performed to estimate a frequency shift for a single 4 millimeter hole drilled into a circuit board at various offset locations with respect to a center of a patch antenna. For comparison purposes, a baseline resonant frequency value for no holes was estimated as 19.4560 GHz. Simulation results were obtained for the following [xholeoffset/yholeoffset] combinations: 19.4420 GHz [0 mm, 0 mm]; 19.4160 GHz [2 mm, 0 mm]; 19.4320 [0 mm, 2 mm]; 19.4460 GHz [2 mm, 2 mm]; and 19.4520 GHz [4 mm, 4 mm]. Thus, the smallest simulated frequency shift was 40 MHz for an xholeoffset/yholeoffset combination of 4mm, 4 mm.

A 3D simulation was also performed to estimate a frequency shift for a single 10 millimeter hole drilled into a circuit board at various offset locations with respect to a center of a patch antenna. For comparison purposes, a baseline resonant frequency value for no holes was estimated as 19.4560 GHz. Simulation results were obtained for the following [xholeoffset/yholeoffset] combinations: 19.2500 GHz [0 mm, 0 mm]; 19.3260 GHz [2 mm, 0 mm]; 19.4460 [0 mm, 2 mm]; 19.4340GHz [2 mm, 2 mm]; and 19.4040 GHz [4 mm, 4 mm]. Thus, the smallest simulated frequency shift was 100 MHz for an xholeoffset/yholeoffset combination of 0 mm, 2 mm.

Thus, based on the 3D simulation results, the resonant frequency monitoring component 202 may be selected that is capable of detecting a frequency shift of 40 MHz or less.

Referring to FIG. 4, a diagram 400 illustrates multiple views of selected portions of the second patch antenna threat event detection layer 106 embedded in the cryptographic PCB 102 depicted in FIG. 1, according to one embodiment. The multiple views include a cross-sectional view 410 that corresponds to the cross-sectional view depicted in FIG. 1, a top view 412 of the second antenna array 112, and a perspective view 414 that illustrates a portion of the second antenna array 112 that includes the second antenna 130.

In the particular embodiment depicted in FIG. 4, the top view 412 illustrates an example in which the second antenna array 112 includes a 4×4 array of antennas. It will be appreciated that alternative number and/or arrangement of antenna elements (including a single patch antenna) may be utilized. The perspective view 414 illustrates that the second antenna 130 of the second antenna array 112 may be communicatively coupled to a resonant frequency (f_{c}) monitoring component 402 by a trace 404. Illustrative, non-limiting examples of methods of detecting a shift in resonant frequency of the second antenna 130 include a PLL circuit, frequency counter(s), or an FM carrier detection circuit such as a radio tuning circuit.

FIG. 5A illustrates a cross-sectional view 500 of a tamper event associated with the second patch antenna threat event detection layer 106, according to one embodiment. For illustrative purposes only, FIG. 5A depicts a physical access attempt 502 that penetrates through the protective cover 126 and the dielectric material 124 into the second embedded patch antenna threat event detection layer 106. It will be appreciated that the physical access attempt 502 may penetrate further into the cryptographic PCB 102.

Referring to FIG. 5B, a diagram 510 illustrates multiple views of the second patch antenna layer 106 after the tamper event of FIG. 5A that results in a resonant frequency shift, according to one embodiment. The physical access attempt 502 of FIG. 5A results in a hole 512 in the second antenna 130. The hole 512 results in a resonant frequency shift that may be detected by the resonant frequency monitoring component 402 that is communicatively coupled to the second antenna 130 by the trace 404.

Based on the 3D simulation results previously described with respect to FIGS. 3A-3B, the resonant frequency monitoring component 402 may be selected that is capable of detecting a frequency shift of 40 MHz or less.

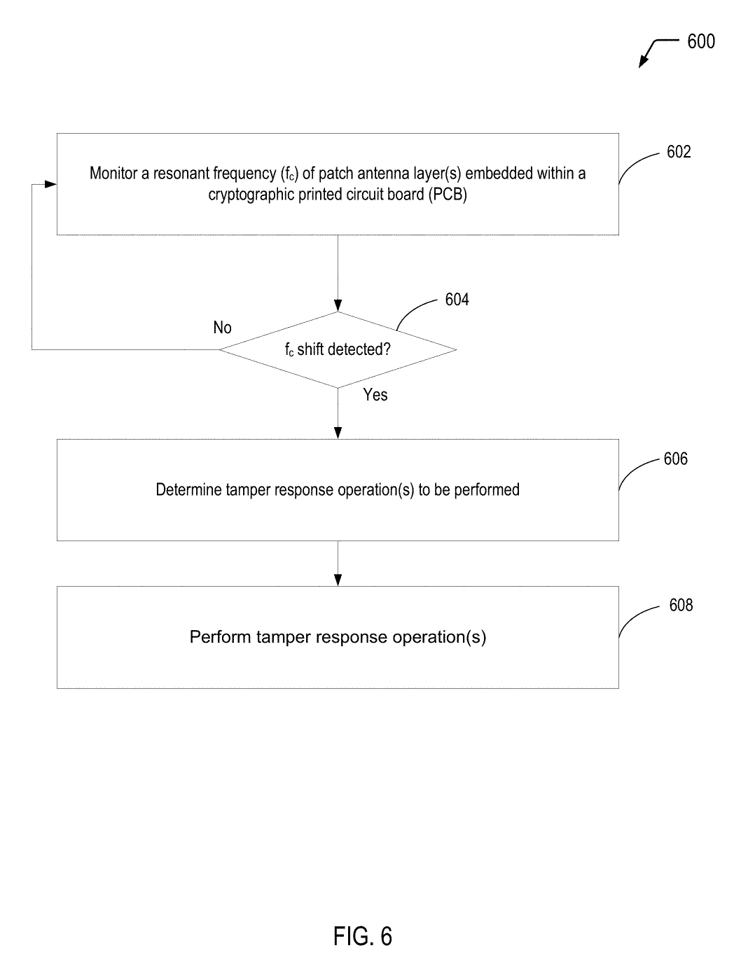

Referring to FIG. 6, a flow diagram illustrates a particular embodiment of a method 600 of utilizing patch antenna layer(s) embedded within a cryptographic PCB for tamper event detection.

The method 600 includes monitoring a resonant frequency (fc) of a patch antenna layer (or multiple patch antenna layers) embedded within a cryptographic PCB, at 602. For example, referring to FIG. 2, the resonant frequency monitoring component 202 may be communicatively coupled to the first antenna 120 of the first antenna array 110 by the trace 204 in order to monitor resonant frequency. As another example, referring to FIG. 4, the resonant frequency monitoring component 402 may be communicatively coupled to the second antenna 130 of the second antenna array 112 by the trace 404 in order to monitor resonant frequency.

The method 600 includes determining whether a resonant frequency shift has been detected, at 604. For example, referring to FIGS. 3A and 3B, the physical access attempt 302 may result in the formation of the hole 312 in the first antenna 120 of the first embedded patch antenna threat event detection layer 104 of the cryptographic PCB 102 depicted in FIG. 1. The hole 312 may result in a resonant frequency shift that may be detected by the resonant frequency monitoring component 202. As another example, referring to FIGS. 5A and 5B, the physical access attempt 502 may result in the formation of the hole 512 in the second antenna 130 of the second embedded patch antenna threat event detection layer 106 of the cryptographic PCB 102 depicted in FIG. 1. The hole 512 may result in a resonant frequency shift that may be detected by the resonant frequency monitoring component 402.

FIG. 6 illustrates that when no resonant frequency shift has been detected, the method 600 returns to 602 for continued monitoring of the resonant frequency of the patch antenna layer(s). When a resonant frequency shift has been detected, the method 600 includes determining one or more tamper response operations to be performed, at 606.

In a particular embodiment, the tamper response operations may be selected based on a location of the physical access attempt. For example, referring to the top view 212 of FIG. 2, the first antenna array 110 may correspond to a 4×4 array of antennas. As another example, referring to the top view 412 of FIG. 4, the second antenna array 112 may correspond to a 4×4 array of antennas. In these examples, the resonant frequency monitoring component may be capable of determining a location of the physical access attempts 302, 502 (e.g., the antenna at [2, 1] x,y location in FIG. 3B and the antenna at [2,3] x,y location in FIG. 5B). The tamper response operations may be selective in order to enable at least partial operation of selected component(s) of the cryptographic PCB 102.

The method 608 further includes performing the tamper response operation(s), at 608. In a particular embodiment, the tamper response operation(s) may correspond to one or more actions to prevent or limit access to a component of a secured device that includes the cryptographic PCB. For example, referring to FIG. 1, the action(s) may include limiting access to an internal component of the secured device 100 (e.g., the cryptographic PCB 102), shutting down the internal component or a portion thereof, transmitting an alarm signal to the internal component, transmitting an alarm signal to an external component (e.g., disposed outside of the protective cover 126), sounding an audible alarm, triggering a visual alarm, rendering the internal component inoperable, physically destroying the internal component or a portion thereof, erasing electronically stored data, encrypting internal data, overwriting stored data with dummy data, or any combination thereof (among other alternatives).

Thus, FIG. 6 illustrates an example of a method of utilizing patch antenna layer(s) embedded within a cryptographic PCB for tamper event detection. A physical access attempt may result in a shift of a resonant frequency of patch antenna(s) embedded within a PCB layer stack of a cryptographic PCB, and detection of such a resonant frequency shift may trigger one or more tamper response operations. In some cases, the tamper detection capability may be sufficient to satisfy FIPS 140-2 Security Requirements for Cryptographic Modules—Level 4 (among other possible security standards).

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A cryptographic printed circuit board (PCB) comprising:
a patch antenna threat event detection layer embedded within a PCB layer stack of the cryptographic PCB, the patch antenna threat event detection layer including at least one antenna;
a resonant frequency monitoring component configured to monitor a resonant frequency associated with the at least one antenna and to trigger one or more tamper response operations responsive to detecting a resonant frequency shift.

2. The cryptographic PCB of claim 1, wherein the at least one antenna includes a plurality of antennas.

3. The cryptographic PCB of claim 2, wherein the plurality of antennas are arranged as an antenna array within the patch antenna threat event detection layer.

4. The cryptographic PCB of claim 1, further comprising a protective cover surrounding the cryptographic PCB.

5. The cryptographic PCB of claim 1, further comprising a second patch antenna threat event detection layer embedded within the PCB layer stack of the cryptographic PCB, the second patch antenna threat event detection layer including at least one antenna.

6. The cryptographic PCB of claim 5, further comprising a second resonant frequency monitoring component configured to monitor a second resonant frequency associated with the at least one antenna of the second patch antenna threat event detection layer and to trigger one or more tamper response operations responsive to detecting a second resonant frequency shift.

7. The cryptographic PCB of claim 6, wherein the resonant frequency shift is indicative of a first physical access attempt at a first surface of the cryptographic PCB, and wherein the second resonant frequency shift is indicative of a second physical access attempt at a second surface of the cryptographic PCB.

8. The cryptographic PCB of claim 7, wherein the first surface is disposed adjacent to a top layer of the PCB layer stack, and wherein the second surface is disposed adjacent to a bottom surface of the PCB layer stack.

9. A method of utilizing a patch antenna layer for tamper event detection, the method comprising:
monitoring a resonant frequency of at least one antenna of a patch antenna layer embedded within a printed circuit board (PCB) layer stack of a cryptographic PCB; and
responsive to detecting a resonant frequency shift of the at least one antenna, triggering a tamper response operation.

10. The method of claim 9, wherein the at least one antenna includes a plurality of antennas.

11. The method of claim 10, wherein the plurality of antennas are arranged as an antenna array within the patch antenna layer.

12. The method of claim 11, further comprising determining a particular antenna of the antenna array that is associated with the resonant frequency shift.

13. The process of claim 12, further comprising selecting the tamper response operation based on the particular antenna that is associated with the resonant frequency shift.

14. The process of claim 9, further comprising:
monitoring a second resonant frequency of a second antenna of a second patch antenna layer embedded within the PCB layer stack; and
responsive to detecting a second resonant frequency shift of the second antenna, triggering a second tamper response operation.

15. The process of claim 14, wherein the resonant frequency shift is indicative of a first physical access attempt at a first surface of the cryptographic PCB, and wherein the second resonant frequency shift is indicative of a second physical access attempt at a second surface of the cryptographic PCB.

16. The process of claim 15, wherein the first surface is disposed adjacent to a top layer of the PCB layer stack, and wherein the second surface is disposed adjacent to a bottom surface of the PCB layer stack.

17. An electronic device comprising:
an electronic component;
a cryptographic printed circuit board (PCB) communicatively coupled to the electronic component, wherein a patch antenna threat event detection layer is embedded within a PCB layer stack of the cryptographic PCB, the first patch antenna threat event detection layer including at least one antenna; and
a resonant frequency monitoring component configured to monitor a resonant frequency associated with the at least one antenna and to trigger one or more tamper response operations responsive to detecting a resonant frequency shift.

18. The electronic device of claim 17, further comprising a protective cover surrounding the electronic component, the cryptographic PCB, and the resonant frequency monitoring component.

19. The electronic device of claim 17, wherein the resonant frequency monitoring component is embedded within the PCB layer stack of the cryptographic PCB.

20. The electronic device of claim 17, wherein the one or more tamper response operations correspond to one or more actions to prevent or limit access to one or more components of the electronic device.
